(19) United States
(12) Patent Application Publication
(10) Pub. No.: US 2020/0280021 A1
(43) Pub. Date: Sep. 3, 2020

(54) FULL-SCREEN DISPLAY PANEL AND MANUFACTURING METHOD THEREOF

(71) Applicant: Wuhan China Star Optoelectronics Semiconductor Display Technology Co., Ltd., Wuhan (CN)

(72) Inventors: Xue LI, Wuhan (CN); Liang SUN, Wuhan (CN); Mian ZENG, Wuhan (CN); Shoucheng WANG, Wuhan (CN)

(73) Assignee: Wuhan China Star Optoelectronics Semiconductor Display Technology Co., Ltd., Wuhan (CN)

(21) Appl. No.: 16/603,849

(22) PCT Filed: Apr. 24, 2019
(86) PCT No.: PCT/CN2019/084077

§ 371 Date: Oct. 9, 2019

(30) Foreign Application Priority Data
Dec. 18, 2018 (CN) 201811551313.0

(51) Int. Cl. H01L 51/52; H01L 27/32; H01L 51/56; H01L 51/00

(52) U.S. Cl. CPC H01L 51/5253; H01L 27/3258; H01L 27/3276; H01L 2251/5338; H01L 51/0008; H01L 27/3246; H01L 2227/323; H01L 51/56

(57) ABSTRACT

A full-screen display panel includes an array substrate; an organic OLED function layer disposed on the array substrate; and a film packaging layer covering the OLED function layer on the array substrate. The full-screen display panel is provided with an opening going through two opposite surfaces of the full-screen display panel and formed by cutting. The array substrate has a first retaining wall circle, a second retaining wall circle, and a main anti-cracking structural circle sequentially disposed around the opening from far to near. The main anti-cracking structural circle includes an anti-cracking groove disposed on the inorganic insulation layers, and an organic anti-cracking strip correspondingly filled in the anti-cracking groove.

### FIELD OF INVENTION

The present disclosure relates to the technical field of displays, and specifically to a flexible full-screen display panel and a manufacturing method thereof.

### BACKGROUND OF INVENTION

Regarding flat panel display technologies, organic light emitting diode (OLED) displays have advantages, such as light, thin, active lighting, fast response speed, large viewable angle, wider color range, high brightness, low power consumption, and being able to fabricate flexible screens. It causes great interest in scientific research and industry, and becomes gradually the third generation display technology followed by liquid crystal displays (LCD).

Currently, design of “full-screen” becomes mainstream of the times, where each supplier is focusing on development of full-screen products with a higher screen occupation ratio. For example, design of notch screens adopted with IPHONE X phone has a screen occupation ratio of 81.15%. Recently developed under-screen camera design is an O-Cut screen design, in which the O-shaped slot is cut in the panel to dispose a camera. Compared with the Notch design, the O-Cut design is closer to effects of a full-screen. A size of the O-Cut region can only be considered by a front camera. Therefore, the size of the O-Cut region is much smaller than a proportion of the entire panel occupied in the notch region. The overall screen advantage of the O-Cut design is more obvious. Therefore, it has a great advantage in a display screen market of the mobile phone.

Although the O-Cut design is closer to the full-screen, it also faces technical problems. In addition, the O-Cut design is particularly difficult to be implemented in an OLED flexible display. Currently, a production method of an OLED panel generally follows the steps followings: first to manufacture a flexible substrate, then to manufacture a thin film transistor (TFT) array layer, an OLED layer, and film packaging layer on the flexible substrate in sequence, finally to perform an O-cutting process, in which an opening is cut by adopting laser, that is, an O-shaped region is cut in an active area of a panel to form an O-shaped slot configured to install a camera. Although devices and a wiring in an array stage can keep away from the O-cut region, during an OLED process, a plurality of layers, such as a hole injection layer, a hole transmission layer, a light emitting layer, an electron transmission layer, an electron injection layer, and a cathode layer, are deposited in an evaporation manner by adopting an open mask. After the O-cut region is cut, OLED organic layers will be exposed at a cut surface, in which water vapor will enter, thereby disabling functions of the panel. In addition, due to physical characteristics of the TFT array layer and inorganic film layers in the film packaging layer, the inorganic film layers easily crack and generate a phenomenon of the crack extension during the O-cutting process, in turn to affect reliability of the panel.

### SUMMARY OF INVENTION

An object of the present disclosure is to provide a full-screen display panel, which has a plurality of retaining wall circles and a main anti-cracking structural circle disposed around a cutting periphery region outside an opening, thereby blocking a crack extension from a plurality of inorganic film layers during a cutting process.

Another object of the present disclosure is further to provide a manufacturing method of a full-screen display panel, in which a crack extension is blocked from a plurality of inorganic film layers during a cutting process, by optimizing a design of a structure around a cutting region.

In order to achieve the above objects, a full-screen display screen is provided in the present disclosure and includes an array substrate, an organic light emitting diode (OLED) function layer disposed on the array substrate, and a film packaging layer covering the OLED function layer on the array substrate;

wherein the full-screen display panel is provided with an opening going through two opposite surfaces of the full-screen display panel and formed by cutting;
wherein the array substrate includes a plurality of inorganic insulation layers, a plurality of organic layers disposed on the inorganic insulation layers, and a plurality of metal layers disposed between the inorganic insulation layers and the organic layers;
wherein the array substrate has a first retaining wall circle, a second retaining wall circle, and a main anti-cracking structural circle sequentially disposed around the opening from far to near;
wherein the main anti-cracking structural circle includes an anti-cracking groove and an organic anti-cracking strip, the anti-cracking groove is disposed on the inorganic insulation layers, and the organic anti-cracking strip is correspondingly filled in the anti-cracking groove; and
wherein the first retaining wall circle, the second retaining wall circle, and the organic anti-cracking strip are formed from the organic layers of the array substrate.

A distance between the second retaining wall circle and the opening is greater than or equal to 350 μm; and

a height of the second retaining wall circle is greater than a height of the first retaining wall circle.

The array substrate is provided with one or more metal windings surrounding the opening, on two sides of the main anti-cracking structural circle, in a region corresponding between the opening and the second retaining wall circle; and

the metal windings are formed from the metal layers of the array substrate.

The array substrate further has one or more auxiliary anti-cracking structural circles, in a region corresponding between the opening and the anti-cracking structural circle;

each of the auxiliary anti-cracking structural circles includes a plurality of anti-cracking slits and a plurality of organic anti-cracking windings, the anti-cracking slits are dug in the inorganic layers, and the organic anti-cracking windings correspondingly fill the anti-cracking slits; and
the organic anti-cracking windings are formed from the organic layers of the array substrate.

The inorganic insulation layers include a buffer layer, a gate insulation layer, and an interlayer insulation layer disposed in sequence, from bottom to up;

the organic layers comprise a planarization layer, a pixel definition layer, and a spacer layer;
the first retaining wall circle is formed from the planarization layer and the pixel definition layer;
the second retaining wall circle is formed from the planarization layer, the pixel definition layer, and the spacer layer; and
the organic anti-cracking strip and the organic anti-cracking windings are formed from the planarization layer.

A spacing strip is provided in the anti-cracking groove, and the anti-cracking groove has an inverted m shape in a longitudinal section thereof; and

a bottom of the organic anti-cracking strip, in a shape of a root of tooth, is embedded in the anti-cracking groove, in a longitudinal section of the main anti-cracking structural circle.

The metal layers comprise a gate metal layer and a source/drain metal layer; and

the metal windings are formed from the gate metal layer, the source/drain metal layer, or the gate metal layer together with the source/drain metal layer.

A manufacturing method of a full-screen display panel is further provided in the present disclosure and includes a step S1 of manufacturing an array substrate, wherein the array substrate includes a plurality of inorganic insulation layers, a plurality of organic layers disposed on the inorganic insulation layers, and a plurality of metal layers disposed between the inorganic insulation layers and the organic layers;

a step S2 of forming an organic light emitting diode (OLED) function layer on the array substrate in an evaporation manner;
a step S3 of obtaining a to-be-cut panel by covering a film packaging layer onto the OLED function layer on the array substrate; and
a step S4 of forming an opening by laser cutting the to-be-cut panel along a boundary of a cutting region;
wherein in the step S1, a region corresponding to the array substrate cut for forming the opening is defined as the cutting region, a region around the cutting region of the array substrate is defined as a cutting peripheral region, and wherein the array substrate has a first retaining wall circle, a second retaining wall circle, and a main anti-cracking structural circle sequentially disposed in the cutting peripheral region around the cutting region from far to near;
wherein the main anti-cracking structural circle includes an anti-cracking groove and an organic anti-cracking strip, the anti-cracking groove is dug in the inorganic layers, and the organic anti-cracking strip is correspondingly filled in the anti-cracking groove; and
wherein the first retaining wall circle, the second retaining wall circle, and the organic anti-cracking strip are formed from the organic layers of the array substrate.

In the step S1, the inorganic insulation layers of the array substrate are fully removed from the cutting region by digging.

The step S2 further includes a step of removing a portion of the OLED function layer corresponding to the cutting peripheral region by adopting laser after the OLED function layer is formed in the evaporation manner; and

in the step S4, the to-be-cut panel is cut from a top side and a bottom side thereof by adopting laser.

Beneficial effects of the present disclosure are that, the full-screen display panel is provided in the present disclosure and includes an array substrate; an organic OLED function layer disposed on the array substrate; and a film packaging layer covering the OLED function layer on the array substrate. The full-screen display panel is provided with an opening going through two opposite surfaces of the full-screen display panel and formed by cutting. The array substrate has a first retaining wall circle, a second retaining wall circle, and a main anti-cracking structural circle sequentially disposed around the opening from far to near. The main anti-cracking structural circle includes an anti-cracking groove and an organic anti-cracking strip, the anti-cracking groove is disposed on the inorganic insulation layers, and the organic anti-cracking strip is correspondingly filled in the anti-cracking groove. The present disclosure can block the crack extension generated in the array substrate and the inorganic film layers in the film packaging layer during the cutting process, by optimizing the cutting peripheral region of the opening.

In order to understand features and technical contents of the present disclosure, please refer to the following detailed description and drawings of the present disclosure. However, the drawings are merely used for reference and illustration and are not intended to limit the present disclosure.

### BRIEF DESCRIPTION OF DRAWINGS

Technical schemes and other beneficial effects of the present disclosure will be apparent from the following detailed description of embodiments of the present disclosure.

In the drawings,

FIG. 1 is a schematic diagram of a cross-sectional structure of a full-screen display panel at an opening, according to the present disclosure.

FIG. 2 is a schematic plan view of the full-screen display panel and a schematic diagram of a partial enlarged view of the opening, according to the present disclosure.

FIG. 3 is a flowchart of a manufacturing method of the full-screen display panel, according to the present disclosure.

FIG. 4 is a schematic diagram of a step S4 of the manufacturing method of the full-screen display panel, according to the present disclosure.

### DETAILED DESCRIPTION OF PREFERRED EMBODIMENTS

In order to further illustrate technical means and effects of the present disclosure, following detailed description will be made in conjunction with preferred embodiments and accompanying drawings of the present disclosure.

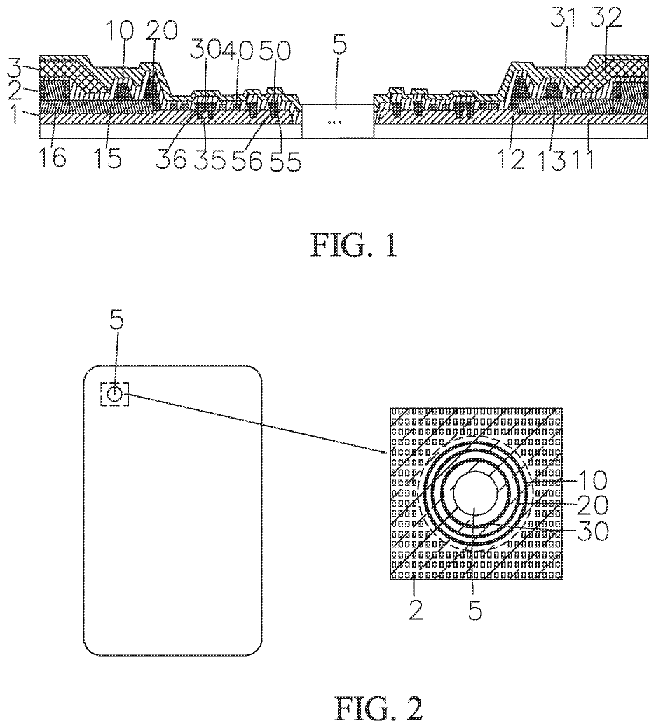

Please refer to FIG. 1-2, a full-screen display panel is firstly, provided in the present disclosure and includes an array substrate 1, an organic light emitting diode (OLED) function layer 2 disposed on the array substrate 1, and a film packaging layer 3 covering the OLED function layer 2 on the array substrate 1.

Specifically, a design of an O-Cut is adopted in the full-screen display panel of the present disclosure, which is provided with an O-shaped opening 5 going through two opposite surfaces of the full-screen display panel, formed by cutting, and subsequently configured to install a camera or other parts.

Specifically, the array substrate 1 includes a plurality of inorganic insulation layers 11, a plurality of organic layers 12 disposed on the inorganic insulation layers 11, a plurality of metal layers 13 disposed between the inorganic insulation layers 11 and the organic layers 12, a plurality of semiconductor layers (not shown) disposed between the inorganic insulation layers 11, and a pixel electrode layer disposed between the organic layers 12.

Specifically, the inorganic insulation layers 11 include a buffer layer, a gate insulation layer, and an interlayer insulation layer (not shown).

Specifically, the organic layers 12 include a planarization layer, a pixel definition layer, and a spacer layer (not shown).

Specifically, the metal layers 13 include a gate metal layer and a source/drain metal layer (not shown).

The metal layers together with the semiconductor layers form a plurality of thin film transistor (TFT) devices 16 and a metal wiring 15, wherein the TFT devices 16 and the metal wiring 15 are both formed to keep away from a cutting region and a cutting periphery region with respect to the opening 5.

Specifically, the pixel electrode layer is disposed on the planarization layer, the pixel definition layer is disposed on the pixel electrode layer and the planarization layer, and surrounds a plurality of pixel openings (not shown) on the pixel electrode layer.

Specifically, the spacer layer is disposed on the pixel definition layer and is configured to support a mask when the OLED function layer 2 is formed in an evaporation manner.

Specifically, the OLED function layer 2 includes such as a hole injection layer, a hole transmission layer, a light emitting layer, an electron transmission layer, an electron injection layer, and a cathode layer.

Specifically, the OLED function layer 2 and the pixel electrode layer commonly form a plurality of OLED devices.

Specifically, a portion of the OLED function layer 2 corresponding to the cutting periphery region is removed, to cause that the OLED function layer 2 is located within an active area outside the cutting periphery region. Thus, the film packaging layer 3 located in the cutting periphery region effectively protects from a periphery of the OLED function layer 2 and prevents the OLED function layer 2 from exposed at a cut surface with respect to the opening 5 and being entered by water vapor.

Specifically, the film packaging layer 3 includes an inorganic barrier layer 31 and an organic buffer layer 32 stacked alternately, wherein the inorganic barrier layer 31 has one more layer in quantities than the organic buffer layer 32.

Specifically, the array substrate 1 has a first retaining wall circle 10, a second retaining wall circle 20, and a main anti-cracking structural circle 30 sequentially disposed around the opening 5 from far to near.

The first retaining wall circle 10 and the second retaining wall circle 20 can play a barrier role when the organic buffer layer 32 of the film packaging layer 3 is formed by an ink jet printer (IJP). Thus, the ink used for forming the organic buffer layer 32 is intercepted from outside the first retaining wall circle 10.

Specifically, a height of the second retaining wall circle is greater than a height of the first retaining wall circle. The first retaining wall circle 10 and the second retaining wall circle 20 are both formed from the organic layers 12 of the array substrate 1. Layer quantities of the organic layers 12 involved in the second retaining wall circle 20 are more than layer quantities of the organic layers 12 involved in the first retaining wall circle 10.

Specifically, the first retaining wall circle 10 is formed from the planarization layer and the pixel definition layer; and the second retaining wall circle 20 is formed from the planarization layer, the pixel definition layer, and the spacer layer.

Specifically, a distance between the second retaining wall circle 20 and the opening 5 needs to be greater than or equal to 350 microns (μm), thereby ensuring packaging effect of the film packaging layer 3 to the active area. It blocks a crack in a plurality of inorganic film layer, such as the inorganic barrier layer 31 in the inorganic insulation layer 11 and the film packaging layer 3 in the array substrate 1, caused by a cutting process used for the opening 5, to extend into the active area. Thus, it avoids subsequent influences on a reliability of the full-screen display panel.

Specifically, the main anti-cracking structural circle 30 is constituted of an anti-cracking groove 35 together with an organic anti-cracking strip 36, wherein the anti-cracking groove 35 is dug in the inorganic insulation layers 11, and the organic anti-cracking strip 36 is correspondingly filled in the anti-cracking groove 35.

It should be explained that, because the opening 5 is cut on the inorganic barrier layer 31 of the film packaging layer 3 by an O-cutting process, although a cutting edge is provided with a certain safety distance from the second retaining wall circle 20, it still has a crack hidden problem. Thus, an extension of the crack will be further blocked by the main anti-cracking structural circle 30. First, the design of the anti-cracking groove 35 is conducive to block the crack extending along the inorganic film layers and plays a barrier role. Secondly, the organic anti-cracking strip 36 belonging to the organic material can play a buffer role, further weakening a phenomenon of the crack extension of the inorganic barrier layer 31 of the film packaging layer 3.

Specifically, a spacing strip is provided in the anti-cracking groove 35, and the anti-cracking groove 35 has an inverted m shape in a longitudinal section thereof, Thus, a bottom of the organic anti-cracking strip 36, in a shape of a root of tooth, is embedded in the anti-cracking groove 35, in a longitudinal section of the main anti-cracking structural circle 30.

Specifically, the array substrate 1 is provided with one or more metal windings 40 surrounding the opening 5, on two sides of the main anti-cracking structural circle 30, in a region corresponding between the opening 5 and the second retaining wall circle 20. Therefore, during the process of cutting the opening 5, the metal windings 40 will block a part of the crack when the crack extends to a position of the metal windings 40 along the inorganic film layers.

Specifically, the metal windings 40 are formed from the metal layers 13 of the array substrate 1. Further, the metal windings are formed from the gate metal layer, the source/drain metal layer, or the gate metal layer together with the source/drain metal layer.

Specifically, the array substrate 1 further has one or more auxiliary anti-cracking structural circles 50, in a region corresponding between the opening 5 and the anti-cracking structural circle 30.

Specifically, each of the auxiliary anti-cracking structural circles 50 is constituted of a plurality of anti-cracking slits 55 and a plurality of organic anti-cracking windings 56, the anti-cracking slits 55 are dug in the inorganic layers 11, and the organic anti-cracking windings 56 correspondingly fill the anti-cracking slits 55. It enhances the blocking effect to the inorganic film layers, such as the inorganic insulation layer 11 of the array substrate 1 and the inorganic barrier layer 31 of the film packaging layer 3, during the process of cutting the opening 5.

Specifically, the organic anti-cracking strip 36 and the organic anti-cracking windings 56 are formed from the planarization layer.

The full-screen display panel of the present disclosure adopts the O-cut design. The full-screen display panel is provided with the opening 5 going through two opposite surfaces of the full-screen display panel and formed by cutting. The present disclosure optimizes the cutting peripheral region of the opening 5. A first retaining wall circle 10, a second retaining wall circle 20, and a main anti-cracking structural circle 30 are sequentially disposed around the opening 5 from far to near. It can effectively block that the crack extension of the array substrate and the inorganic film layers in the film packaging layer caused by the process of cutting the opening, thereby avoiding subsequent influences on the reliability of the full-screen display panel.

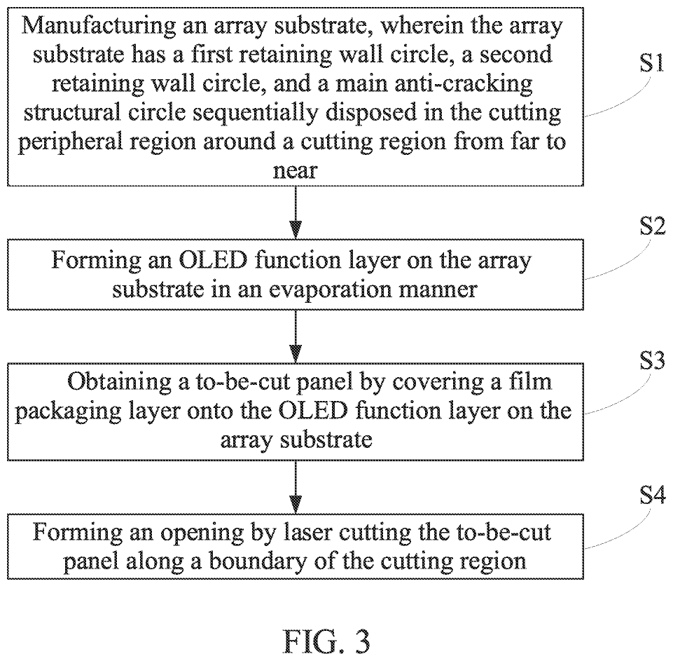

Please refer to FIG. 3, based on the same inventive concept, a manufacturing method of a full-screen display panel is provided in the present disclosure, the manufacturing method includes the followings.

In a step S1, an array substrate 10 is manufactured.

Specifically, the array substrate 1 includes a plurality of inorganic insulation layers 11, a plurality of organic layers 12 disposed on the inorganic insulation layers 11, a plurality of metal layers 13 disposed between the inorganic insulation layers 11, a plurality of semiconductor layers disposed between the organic layers 12 and the inorganic insulation layers 11, and a pixel electrode layer disposed between the organic layers 12.

Specifically, the inorganic insulation layers 11 include a buffer layer, a gate insulation layer, and an interlayer insulation layer.

Specifically, the organic layers include a planarization layer, a pixel definition layer, and a spacer layer.

Specifically, the metal layers 13 include a gate metal layer and a source/drain metal layer.

The metal layers together with the semiconductor layers form a plurality of TFT devices 16 and a metal wiring 15, wherein the TFT devices 16 and the metal wiring 15 are both formed to keep away from a cutting region and a cutting periphery region with respect to the opening 5.

Specifically, the pixel electrode layer is disposed on the planarization layer, the pixel definition layer is disposed on the pixel electrode layer and the planarization layer, and surrounds a plurality of pixel openings on the pixel electrode layer.

Specifically, the spacer layer is disposed on the pixel definition layer and is configured to support a mask when the OLED function layer 2 is formed in an evaporation manner.

In a step S2, an OLED function layer 2 is formed on the array substrate 10 in an evaporation manner.

Specifically, the OLED function layer 2 includes such as a hole injection layer, a hole transmission layer, a light emitting layer, an electron transmission layer, an electron injection layer, and a cathode layer.

Specifically, the OLED function layer 2 and the pixel electrode layer commonly form a plurality of OLED devices.

The step S2 further includes a step of removing a portion of the OLED function layer corresponding to the cutting peripheral region by adopting laser after the OLED function layer is formed in the evaporation manner. It is cause that the OLED function layer 2 is located within an active area outside the cutting periphery region. Thus, the film packaging layer 3 located in the cutting periphery region effectively protects from a periphery of the OLED function layer 2 and prevents the OLED function layer 2 from exposed at a cut face with respect to the opening 5 and being entered by water vapor.

In a step S3, a to-be-cut panel is obtained by covering a film packaging layer 3 onto the OLED function layer 2 on the array substrate 1.

Specifically, the film packaging layer 3 includes an inorganic barrier layer 31 and an organic buffer layer 32 stacked alternately, wherein the inorganic barrier layer 31 has one more layer in quantities than the organic buffer layer 32.

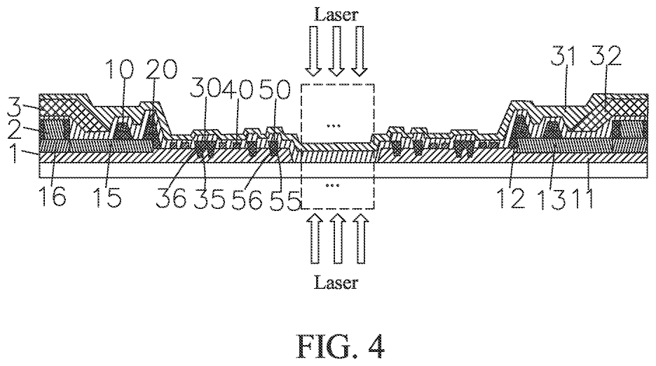

In a step S4, shown in FIG. 4, an opening 5 is formed by laser cutting the to-be-cut panel along a boundary of a cutting region;

Specifically, in the step S1, a region corresponding to the array substrate cut for forming the opening is defined as the cutting region, a region around the cutting region of the array substrate 1 is defined as a cutting peripheral region, and wherein the array substrate 1 has a first retaining wall circle 10, a second retaining wall circle 20, and a main anti-cracking structural circle 30 sequentially disposed in the cutting peripheral region around the opening 5 from far to near.

It should be explained that, in the step S3, the first retaining wall circle 10 and the second retaining wall circle 20 can play a barrier role when the organic buffer layer 32 of the film packaging layer 3 is formed by an ink jet printer (IJP). Thus, the ink used for forming the organic buffer layer 32 is intercepted from outside the first retaining wall circle 10.

Specifically, a height of the second retaining wall circle is greater than a height of the first retaining wall circle. The first retaining wall circle 10 and the second retaining wall circle 20 are both formed from the organic layers 12 of the array substrate 1. Layer quantities of the organic layers 12 involved in the second retaining wall circle 20 are more than layer quantities of the organic layers 12 involved in the first retaining wall circle 10.

Specifically, the first retaining wall circle 10 is formed from the planarization layer and the pixel definition layer; and the second retaining wall circle 20 is formed from the planarization layer, the pixel definition layer, and the spacer layer.

Specifically, a distance between the second retaining wall circle 20 and the opening 5 needs to be greater than or equal to 350 microns (μm), thereby ensuring packaging effect of the film packaging layer 3 to the active area. It blocks a crack in a plurality of inorganic film layer, such as the inorganic barrier layer 31 in the inorganic insulation layer 11 and the film packaging layer 3 in the array substrate 1, caused by a cutting process used for the opening 5, to extend into the active area, thereby avoiding subsequent influence on the reliability of the full-screen display panel.

It should be explained that, in the step S4, because the opening 5 is cut on the inorganic barrier layer 31 of the film packaging layer 3 by an O-cutting process, although a cutting edge is provided with a certain safety distance from the second retaining wall circle 20, it still has a crack hidden problem. Thus, an extension of the crack will be further blocked by the main anti-cracking structural circle 30. First, the design of the anti-cracking groove 35 is conducive to block the crack extending along the inorganic film layers and plays a barrier role. Secondly, the organic anti-cracking strip 36 belonging to the organic material can play a buffer role, further weakening a phenomenon of the crack extension of the inorganic barrier layer 31 of the film packaging layer 3.

Specifically, in the step S1, the main anti-cracking structural circle 30 is constituted of an anti-cracking groove 35 together with an organic anti-cracking strip 36, wherein the anti-cracking groove 35 is dug in the inorganic insulation layers 11, and the organic anti-cracking strip 36 is correspondingly filled in the anti-cracking groove 35.

Specifically, a spacing strip is provided in the anti-cracking groove 35, and the anti-cracking groove 35 has an inverted m shape in a longitudinal section thereof. Thus, a bottom of the organic anti-cracking strip 36, in a shape of a root of tooth, is embedded in the anti-cracking groove 35, in a longitudinal section of the main anti-cracking structural circle 30.

Specifically, the array substrate 1 is provided with one or more metal windings 40 surrounding the opening 5, on two sides of the main anti-cracking structural circle 30, in a region corresponding between the opening 5 and the second retaining wall circle 20.

Specifically, the metal windings 40 are formed from the metal layers 13 of the array substrate 1. Further, the metal windings are formed from the gate metal layer, the source/drain metal layer, or the gate metal layer together with the source/drain metal layer.

Further, during the process of cutting the opening 5 in the step S4, the metal windings 40 will block a part of the crack when the crack extends to a position of the metal windings 40 along the inorganic film layers.

Specifically, the array substrate 1 further has one or more auxiliary anti-cracking structural circles 50, in a region corresponding between the opening 5 and the anti-cracking structural circle 30.

Specifically, in the step S1, each of the auxiliary anti-cracking structural circles 50 is constituted of a plurality of anti-cracking slits 55 and a plurality of organic anti-cracking windings 56, the anti-cracking slits 55 are dug in the inorganic layers 11, and the organic anti-cracking windings 56 correspondingly fill the anti-cracking slits 55. It enhances the blocking effect to the inorganic film layers, such as the inorganic insulation layer 11 of the array substrate 1 and the inorganic barrier layer 31 of the film packaging layer 3, during the process of cutting the opening 5.

Specifically, the organic anti-cracking strip 36 and the organic anti-cracking windings 56 are formed from the planarization layer.

Specifically, in the step S1, the inorganic insulation layers 11 of the array substrate 1 are fully removed from the cutting region by digging. Because the inorganic film layers easily crack, possibility of crack generation is fundamentally reduced by the inorganic insulation layers 11 of the array substrate 1 fully removed from the cutting region in a digging manner.

Specifically, in the step S4, the to-be-cut panel is cut from a top side and a bottom side thereof by adopting laser, thereby reducing the phenomenon of more cracks due to excessive cutting energy used to a single-side.

The manufacturing method of the full-screen display panel of the present disclosure can effectively block the crack extension of the array substrate 1 and the inorganic film layers in the film packaging layer 3 during the cutting process.

In summary, the full-screen display panel is provided in the present disclosure and includes an array substrate; an organic OLED function layer disposed on the array substrate; and a film packaging layer covering the OLED function layer on the array substrate. The full-screen display panel is provided with an opening going through two opposite surfaces of the full-screen display panel and formed by cutting. The array substrate has a first retaining wall circle, a second retaining wall circle, and a main anti-cracking structural circle sequentially disposed around the opening from far to near. The main anti-cracking structural circle includes an anti-cracking groove and an organic anti-cracking strip, the anti-cracking groove is disposed on the inorganic insulation layers, and the organic anti-cracking strip is correspondingly filled in the anti-cracking groove. The present disclosure can block the crack extension generated in the array substrate and the inorganic film layers in the film packaging layer during the cutting process, by optimizing the cutting peripheral region of the opening.

In the above description, various other changes and modifications can be made in accordance with technical solutions and technical concept of the present disclosure, and all such changes and modifications are within the scope of the claims of the present disclosure.

1. A full-screen display panel, comprising:
an array substrate;
an organic light emitting diode (OLED) function layer disposed on the array substrate; and
a film packaging layer covering the OLED function layer on the array substrate;
wherein the full-screen display panel is provided with an opening going through two opposite surfaces of the full-screen display panel and formed by cutting;
wherein the array substrate comprises a plurality of inorganic insulation layers, a plurality of organic layers disposed on the inorganic insulation layers, and a plurality of metal layers disposed between the inorganic insulation layers and the organic layers;
wherein the array substrate has a first retaining wall circle, a second retaining wall circle, and a main anti-cracking structural circle sequentially disposed around the opening from far to near;
wherein the main anti-cracking structural circle comprises an anti-cracking groove and an organic anti-cracking strip, the anti-cracking groove is dug in the inorganic insulation layers, and the organic anti-cracking strip is correspondingly filled in the anti-cracking groove; and
wherein the first retaining wall circle, the second retaining wall circle, and the organic anti-cracking strip are formed from the organic layers of the array substrate.

2. The full-screen display panel as claimed in claim 1, wherein a distance between the second retaining wall circle and the opening is greater than or equal to 350 μm; and a height of the second retaining wall circle is greater than a height of the first retaining wall circle.

3. The full-screen display panel as claimed in claim 1, wherein the array substrate is provided with one or more metal windings surrounding the opening, on two sides of the main anti-cracking structural circle, in a region corresponding between the opening and the second retaining wall circle; and
the metal windings are formed from the metal layers of the array substrate.

4. The full-screen display panel as claimed in claim 1, wherein the array substrate further has one or more auxiliary anti-cracking structural circles, in a region corresponding between the opening and the anti-cracking structure; each of the auxiliary anti-cracking structural circles comprises a plurality of anti-cracking slits and a plurality of organic anti-cracking windings, the anti-cracking slits are dug in the inorganic layers, and the organic anti-cracking windings correspondingly fill the anti-cracking slits; and
the organic anti-cracking windings are formed from the organic layers of the array substrate.

5. The full-screen display panel as claimed in claim 4, wherein the inorganic insulation layers comprise a buffer layer, a gate insulation layer, and an interlayer insulation layer;
the organic layers comprise a planarization layer, a pixel definition layer, and a spacer layer disposed in sequence, from bottom to up;
the first retaining wall circle is formed from the planarization layer and the pixel definition layer;
the second retaining wall circle is formed from the planarization layer, the pixel definition layer, and the spacer layer; and
the organic anti-cracking strip and the organic anti-cracking windings are formed from the planarization layer.

6. The full-screen display panel as claimed in claim 1, wherein a spacing strip is provided in the anti-cracking groove, and the anti-cracking groove has an inverted m shape in a longitudinal section thereof; and
a bottom of the organic anti-cracking strip, in a shape of a root of tooth, is embedded in the anti-cracking groove, in a longitudinal section of the main anti-cracking structural circle.

7. The full-screen display panel as claimed in claim 3, wherein the metal layers comprise a gate metal layer and a source/drain metal layer; and
the metal windings are formed from the gate metal layer, the source/drain metal layer, or the gate metal layer together with the source/drain metal layer.

8. A manufacturing method of a full-screen display panel, comprising:
a step S1 of manufacturing an array substrate, wherein the array substrate comprises a plurality of inorganic insulation layers, a plurality of organic layers disposed on the inorganic insulation layers, and a plurality of metal layers disposed between the inorganic insulation layers and the organic layers;
a step S2 of forming an organic light emitting diode (OLED) function layer on the array substrate in an evaporation manner;
a step S3 of obtaining a to-be-cut panel by covering a film packaging layer onto the OLED function layer on the array substrate; and
a step S4 of forming an opening by laser cutting the to-be-cut panel along a boundary of a cutting region;
wherein in the step S1, a region corresponding to the array substrate cut for forming the opening is defined as the cutting region, a region around the cutting region of the array substrate is defined as a cutting peripheral region, and wherein the array substrate has a first retaining wall circle, a second retaining wall circle, and a main anti-cracking structural circle sequentially disposed in the cutting peripheral region around the cutting region from far to near;
wherein the main anti-cracking structural circle comprises an anti-cracking groove and an organic anti-cracking strip, the anti-cracking groove is dug in the inorganic layers, and the organic anti-cracking strip is correspondingly filled in the anti-cracking groove; and
wherein the first retaining wall circle, the second retaining wall circle, and the organic anti-cracking strip are formed from the organic layers of the array substrate.

9. The manufacturing method of the full-screen display panel as claimed in claim 8, wherein in the step S1, the inorganic insulation layers of the array substrate are fully removed from the cutting region by digging.

10. The manufacturing method of the full-screen display panel as claimed in claim 8, wherein the step S2 further comprises a step of removing a portion of the OLED function layer corresponding to the cutting peripheral region by adopting laser after the OLED function layer is formed in the evaporation manner; and
in the step S4, the to-be-cut panel is cut from a top side and a bottom side thereof by adopting laser.
